(19) United States
(12) Patent Application Publication
(10) Pub. No.: US 2014/0233185 A1
(43) Pub. Date: Aug. 21, 2014

(54) ELECTRONIC DEVICE WITH FANS

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: YOU-XI WEN, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/850,259

(22) Filed: Mar. 25, 2013

(30) Foreign Application Priority Data
Feb. 19, 2013 (CN) 201310053281.2

(51) Int. Cl. H05K 7/20

(52) U.S. Cl. CPC H05K 7/20172
USPC 361/695

(57) ABSTRACT

An electronic device includes a bottom wall, a board perpendicularly connected to the bottom wall, a fan, and a frame receiving the fan. The board defines a vent and two notches above the vent. Each notch extends through a top side of the board. A power connector is mounted to the bottom wall, adjacent to the vent. A switch is mounted to a side of the frame and is electrically connected to the fan. Two fixing members are mounted to the frame to engage in the notches in a vertical direction, therefore, the switch is electrically connected to the power connector.

### BACKGROUND

1. Technical Field

The present disclosure relates to an electronic device including fans.

2. Description of Related Art

Fans mounted in servers are often electrically connected to motherboards to get power. As a result, in case a fan needs to be replaced, the power supplied for the server system needs to be turned off first, which is not desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of an electronic device, wherein the electronic device includes a frame and a fan.

FIG. 2 is a partially exploded, isometric view of FIG. 1.

FIG. 3 is an enlarged view of the assembled fan and frame of FIG. 2, but viewed from another perspective.

FIG. 4 is an exploded, isometric view of FIG. 3.

FIG. 5 is similar to FIG. 4, but viewed from another perspective.

FIG. 6 is a cross-sectional view of FIG. 1, taken along the line VI-VI.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

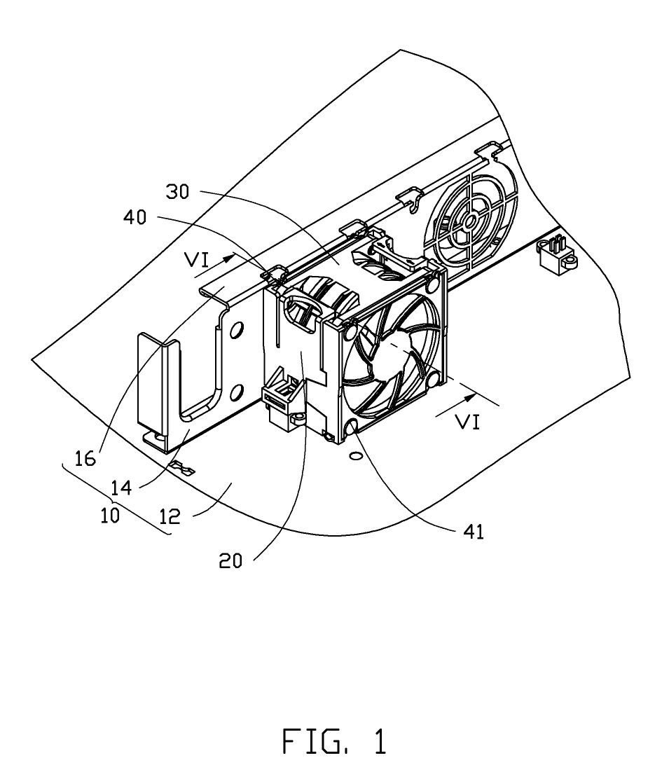

FIG. 1 is an exemplary embodiment of an electronic device. The electronic device includes a chassis 10, a frame 20, a fan 30, two fixing members 40, and a plurality of fasteners 41.

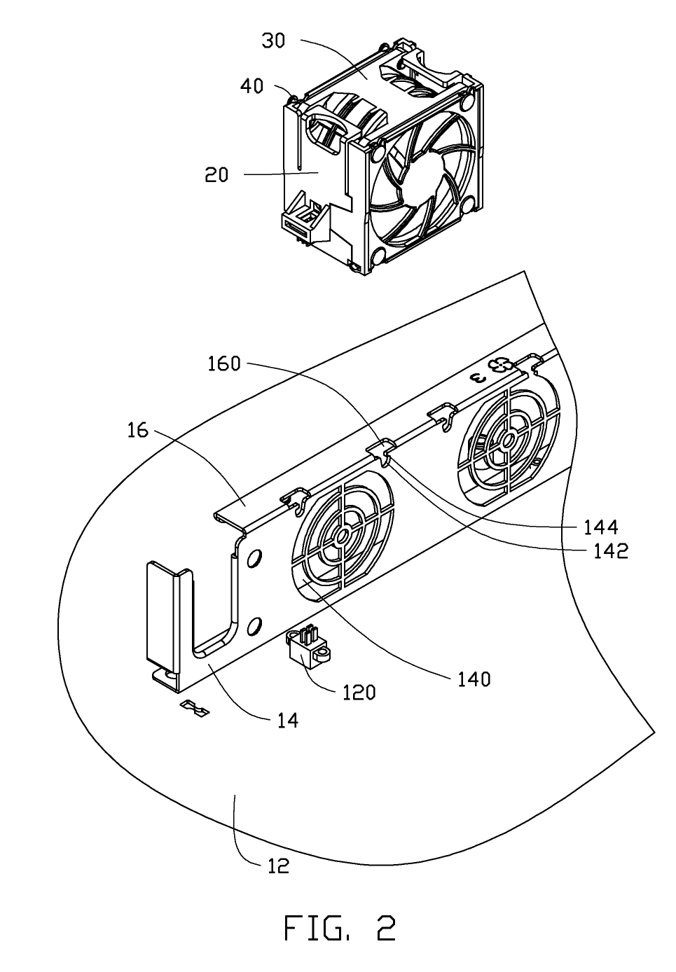

FIG. 2 shows that the chassis 10 includes a bottom wall 12, a board 14 perpendicularly extending up from the bottom wall 12, and an extension plate 16 perpendicularly extending out from a top end of the board 14 opposite to the bottom wall 12. The board 14 defines a vent 140 and two U-shaped notches 142 adjacent to opposite ends of a top side of the vent 140. Each notch 142 extends through a top side of the board 14. A blocking piece 144 extends from a sidewall bounding each notch 142 opposite to the other notch 142, adjacent to the top side of the board 14. The extension plate 16 defines two slots 160 communicating with the corresponding notches 142. A power connector 120 protrudes from the bottom wall 12, adjacent to a lateral side of the vent 140, and is electrically connected to a motherboard (not shown) mounted on the bottom wall 12.

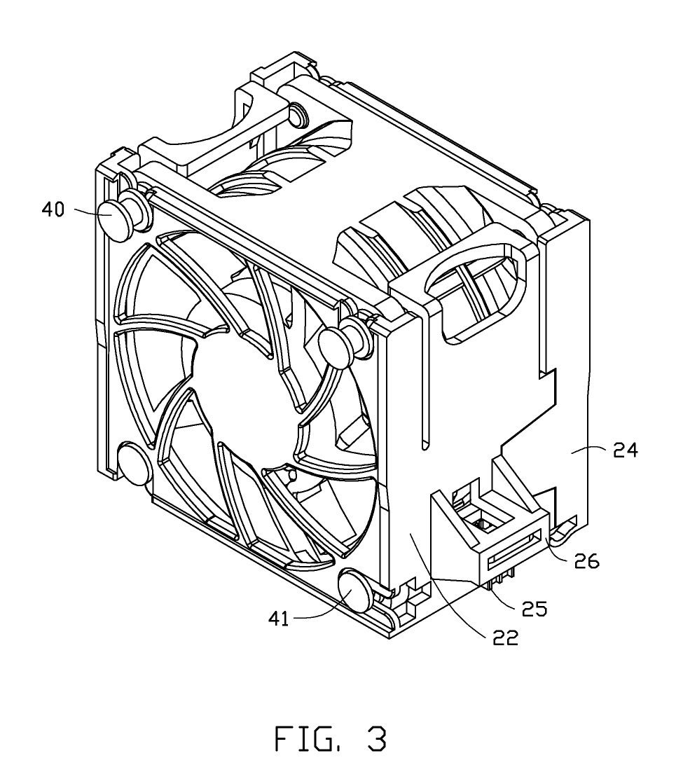

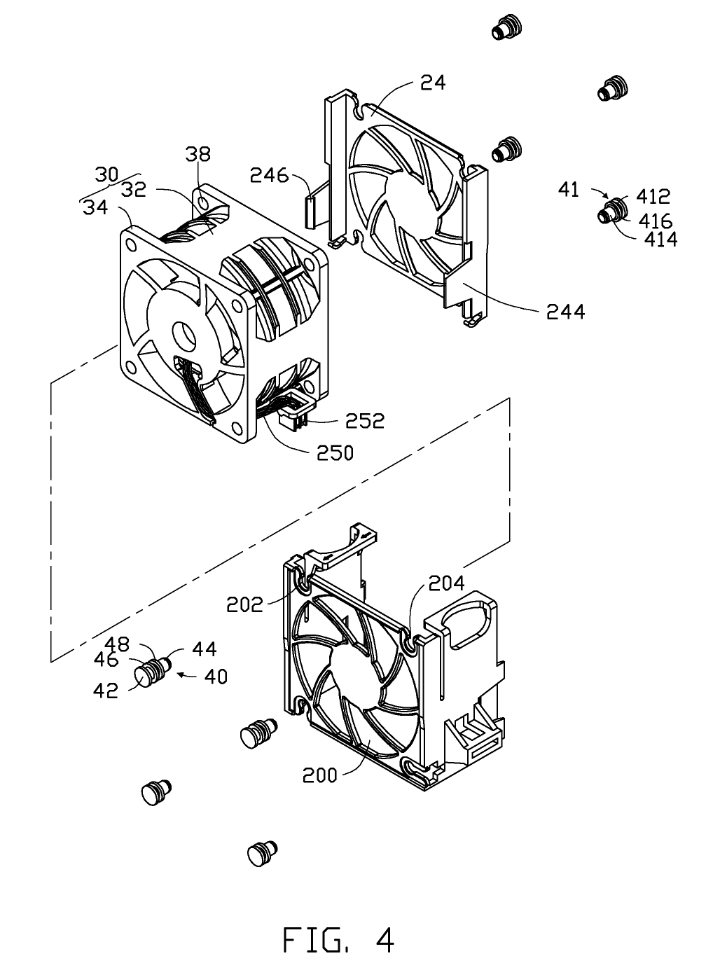

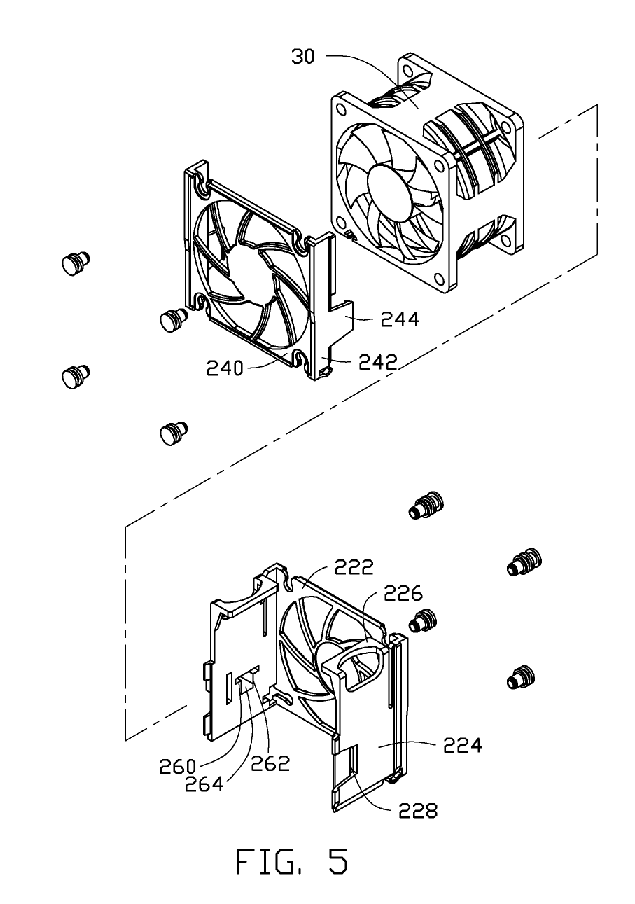

FIGS. 3 to 5 show that the frame 20 includes a receiving member 22, a cover 24, and a switch 25. The receiving member 22 includes a first sidewall 222 and two lateral walls 224 perpendicularly extending out from opposite sides of the first sidewall 222. Two handles 226 extend from the top ends of the lateral walls 224 toward each other. A latching hole 228 is defined in a center of each lateral wall 224. A receiving portion 26 extends out from a lower portion of one of the lateral walls 224 opposite to the handles 226. The receiving portion 26 defines a T-shaped receiving space 260 having an opening 262 extending through an inner surface of the lateral wall 224 and a cutout 264 extending through a bottom of the receiving portion 26. The cover 24 includes a second sidewall 240, two extension pieces 242 perpendicularly extending out from opposite sides of the cover 24, and two hooks 244 extending out from the extension pieces 242 away from the second sidewall 240. A projection 246 protrudes from an inner surface of each hook 244 toward the other hook 244. The switch 25 is substantially T-shaped. A plurality of cables 250 extends out of a top of the switch 25 and is electrically connected to the fan 30. A connecting portion 252 is electrically connected to the cables 260 and extends from a bottom of the switch 25. The first sidewall 222 and the second sidewall 240 each define a vent 200 and four through holes 202 around the vent 200. Each through hole 202 defines an opening 204 less than other parts of the through hole 202 in width and extending through a corresponding side of the first sidewall 222 or second sidewall 240 adjacent to the through hole 202.

The fan 30 includes a main body 32 and two end boards 34 connected to opposite sides of the main body 32. Each end board 34 defines four fixing holes 38 in four corners.

The fixing members 40 and the fasteners 41 are made of resilient material, such as rubber. Each fixing member 40 includes a head 42 and a pole 44 extending from the head 42. Two annular protrusions 46 and 48 protrude from a circumference of the pole 44.

Each fastener 41 includes a head 412 and a pole 414. An annular protrusion 416 protrudes from a circumference of the pole 414.

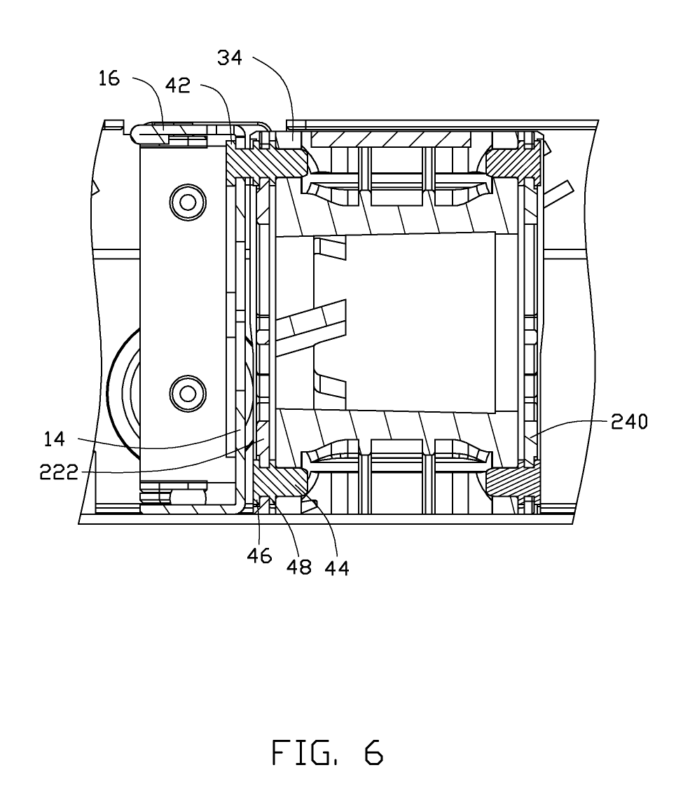

FIGS. 1 and 6 show that in assembly, the fixing members 40 extend through the openings 204 positioned at the top side of the first sidewall 222 opposite to the receiving portion 26, and are engaged in the corresponding through holes 202. The protrusions 46 and 48 sandwich the first sidewall 222. The heads 42 are positioned out of the frame 20. The fasteners 41 are engaged in the other through holes 202; therefore, lower portions of the first sidewall 222 and the second sidewall 240 are sandwiched between the heads 412 and the corresponding protrusions 416.

The switch 25 is received in the receiving space 260 through the opening 262. The connecting portion 252 extends out of the receiving space 260 through the cutout 264. The fan 30 is received in the receiving member 22. The corresponding poles 44 and 414 are engaged in the fixing holes 38 of one of the end board 32. The cover 24 is then mounted to the frame 22. The projections 246 are engaged in the latching holes 228. Therefore, the fan 30 is sandwiched between the receiving member 22 and the cover 24. The poles 414 mounted to the cover 24 are engaged in the other fixing holes 38. The protrusions 416 and 48 are sandwiched between the fan 30 and the frame 20.

The frame 20 together with the fan 30 is mounted to the board 14 from top to bottom. The portion of each pole 44 between the corresponding head 42 and the corresponding protrusion 46 is engaged in one of the notches 142 and is blocked by the corresponding blocking piece 144. The heads 42 extend through the slots 160 and are blocked by a side of the board 14 away from the fan 30. The protrusions 46 are sandwiched between the board 14 and the frame 20. The connecting portion 252 is electrically and is detachably coupled to the power connector 120.

If uninstalling the fan 30, the power of the electronic device does not need to be turned off; the frame 20 only needs to be pulled upward, to disengage the connecting portion 252 from the power connector 120. Therefore, the power supplied for the fan 30 is turned off.

In another embodiment, the fasteners 41 can be replaced by screws or by other fixing structures.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device, comprising:
a bottom wall;
a power connector mounted on the bottom wall;
a board perpendicularly mounted on the bottom wall, and defining a first vent adjacent to the power connector, and two notches above the first vent and extending through a top side of the board opposite to the bottom wall;
a fan;
a frame receiving the fan, wherein a switch electrically connected to the fan is mounted to a lower portion of a side of the frame; and
two fixing members mounted to the frame, wherein the fixing members are engaged in the notches, and mount the frame together with the fan to the board, the switch is detachably coupled to the power connector.

2. The electronic device of claim 1, wherein a receiving portion protrudes from the lower portion of the corresponding side of the frame to receive the switch, the receiving portion defines a cutout in a bottom, the switch comprises a connecting portion at a bottom, the connecting portion extends out of the receiving portion through the cutout to be electrically coupled to the power connector.

3. The electronic device of claim 2, wherein the frame comprises a receiving member and a cover, the receiving member comprises a first sidewall and two lateral walls perpendicularly extending out from the first sidewall, each lateral wall defines a latching hole, the cover comprises a second sidewall and two hooks extending out from opposite sides of the second sidewall to engaged in the latching holes, the first and second sidewalls each define a second vent corresponding to the first vent.

4. The electronic device of claim 3, wherein two handles extend from top ends of the lateral walls opposite to the receiving portion and toward each other.

5. The electronic device of claim 1, wherein each fixing member comprises a head and a pole extending from a side of the head, the pole extends through the frame to be engaged in the fan, a portion of the pole adjacent to the head is engaged in a corresponding one of the notches, the head is blocked by a side of the board away from the fan.

6. The electronic device of claim 5, wherein each fixing member further comprises a resilient protrusion protruding from a circumference of the pole to be sandwiched between the fan and the frame.

7. The electronic device of claim 5, wherein each fixing member further comprises two resilient protrusions protruding from a circumference of the pole, one of the protrusions is sandwiched between the fan and the frame, the other protrusion is sandwiched between the frame and the board.

8. The electronic device of claim 5, wherein the frame comprises a sidewall defining two through holes, each through hole having an opening extending through a top side of the sidewall, the fixing members extend through the corresponding openings and are engaged in the through holes.

9. The electronic device of claim 5, wherein a blocking piece extends from a sidewall bounding the notch opposite to the other notch, to block the pole of a corresponding one of the fixing members.

10. The electronic device of claim 1, wherein the fixing members are made of resilient material.
